(19) United States
(12) Patent Application Publication
(10) Pub. No.: US 2003/0084397 A1
(43) Pub. Date: May 1, 2003

(54) Apparatus and method for a distributed raid

(75) Inventor: Nir Peleg, Beer Yaccov (IL)

Correspondence Address: SUGHRUE MION, PLLC, 2100 Pennsylvania Avenue, NW, Washington, DC, 20037-3213, US

(73) Assignee: EXANET CO.

(21) Appl. No.: 09/984,850

(22) Filed: Oct. 31, 2001

(51) Int. Cl. G11C 29/00

(52) U.S. Cl. 714/770

(57) ABSTRACT

The invention presented is targeted to provide a system solution for a networked redundant array of independent disks (RAID). Disclosed are a system and method for the connection of RAID system as well as the ability to cascade RAID solutions to provide high-end storage solutions.

### BACKGROUND OF THE PRESENT INVENTION

1. Technical Field of the Invention

The present invention relates generally to redundant array of independent disks (RAID) and more specifically to the implementation of a distributed RAID system over a network.

2. Description of the Related Art

There will now be provided a discussion of various topics to provide a proper foundation for understanding the present invention.

RAID systems began as implementations of a redundant array of inexpensive disks and were first suggested as early as 1988. Such systems have quickly developed into what is referred to today as a redundant array of independent disks. This development was possible due to the rapidly declining prices of disks that allowed for sophisticated implementations of systems targeted at providing reliable storage. In addition to the storage reliability, the systems provide the necessary performance, higher capacity, and overall decrease in costs for securing mission critical data. Background information about RAID systems is provided in a Dell Computer Corporation white paper titled “RAID Technology”, herein by incorporated by reference.

Most RAID technologies involve a storage technique commonly known as data striping. Data striping is used to map data over multiple physical drives in an array of drives. In fact, this process creates a large virtual drive. The data to be written to the array of drives is subdivided into consecutive segments or stripes that are written sequentially across the drives in the array. Each data stripe has a defined size or depth in blocks. At its most basic, data striping is also known as RAID 0. It should be noted, however, that this is not a true RAID implementation, since RAID 0 does not provide for fault tolerance capabilities (e.g., calculation of parity data to allow for data recovery or data redundancy by writing the same data to more than one disk strip).

There are several levels of RAID array implementations. Referring to FIG. 1A, the simplest RAID array known as RAID 1 is illustrated. A RAID 1 array 100 comprises a RAID 1 controller 110 and a plurality of data storage devices 120-1 to 120-n that store multiple sets of data, where n defines the number of data storage devices in the RAID 1 system 100. The network 115 connects each data storage device 120 to the RAID 1 controller 110. Each data storage device 120 comprises one or more data drives 122. As used herein, the term “data drive” encompasses the widest possible meaning and includes, but is not limited to, hard disks, arrays of disks, solid-state disks, discrete memory, cartridges and other devices capable of storing information.

Utilizing a storage method known as mirroring, data storage is normally done using two data storage devices 120 in parallel, such that two copies of the same piece of data are kept. It should be noted that the implementation is not limited to storage of two sets of data. The use of more data storage devices 120 provides for the storage of more mirrored set of data. This may be desirable if increased reliability is required. In case of a data drive failure, read and writes are directed to the surviving data drive (or data drives). replacement data drive is rebuilt using the data stored on the surviving data drive (or data drives).

A RAID 2 array provides additional data protection to a basic striped array. A RAID 2 array uses an error checking and correction method (e.g., Hamming code) that groups data bits and check bits together. Because commercially available data drives do not support error checking and correction code, RAID 2 arrays have not been implemented commercially.

A RAID 3 array is a type of striped array that utilizes a more suitable method of data protection than a RAID 2 array. A RAID 3 array uses parity information for data recovery and this parity information is stored on a dedicated parity drive. The remaining data drives in the RAID 3 array are configured to use small (byte-level) data stripes. If a large data record is being stored, these small data stripes will distribute it across all the data drives comprising the RAID 3 array. Thus, the overall performance versus a single data drive is enhanced since the large data record is transferred in parallel to and from all the data drives comprising the RAID 3 array.

Data striping, in conjunction with parity calculations, provides for data recovery in the event that there is a data drive failure. Parity values are calculated for the data in each data stripe on a bit-by-bit basis. If even parity is used, if the sum of a given bit position is odd, the parity value for that bit position is set to 1. It follows that, if the sum for a given bit position is even, the parity bit is set to 0. Conversely, if odd parity is used and if the sum of a given bit position is odd, the parity value for that bit position is set to 0. Likewise, if the sum for a given bit position is even, the parity bit is set to 1.

RAID 3 arrays typically use more sophisticated data recovery processes than do mirrored data arrays (e.g., a RAID 1 array). In the case of a data drive failure in a RAID 3 array, an exclusive OR (XOR) function is used, along with the data and parity information on the surviving drives, to regenerate the data on the failed data drive. However, since all the parity data is written to a single parity drive, a RAID 3 array suffers from a write bottleneck. When data is written to the RAID 3 array, existing parity information is typically read from the parity drive and new parity information must always be written to the parity drive before the next write request can be fulfilled.

A RAID 4 array differs somewhat from a RAID 3 array. A RAID 4 array, however, uses data stripes that are of sufficient size (i.e., depth) to accommodate large data records. In other words, a large data record can be stored in a single data stripe in a RAID 4 array, whereas the same data record stored in a RAID 3 array would be distributed across many data stripes due to the small stripe size (block-level versus byte-level).

Referring to FIG. 1B, a more advanced RAID 5 implementation is illustrated. The RAID 5 array 130 is designed to overcome limitations found in RAID 3 and RAID 4 arrays. The array consists of a RAID 5 controller 140 and a plurality of data drives 150-1 to 150-3. In each data drive 150-1 to 150-3, there is a portion dedicated for storing parity information 155-1 to 155-3. The stored parity information is added to the data storage in order to assist in data recovery in cases of data drive failure. By adding parity information, any defective portions of stored data can be reconstructed. Data recovery in a RAID 5 array is accomplished by computing the XOR of information on the array's surviving data drives (see above). Because the parity information is distributed among all the data drives comprising the RAID 5 array, the loss of any one data drive reduces the availability of both data and parity information until the failed data drive is regenerated.

In a RAID 5 array, distribution of the parity information helps in reducing the bottleneck created in writing parity information into a single data drive. However, adding parity does add latency due to the calculation of parity, reading portions of data, and updating parity information. Data written to the RAID 5 array 140 is placed in stripes on each of the data drives 150-1 to 150-3. Similarly, the parity information is distributed in stripes 155-1 to 155-3 of the data drives 150-1 to 150-3. For example, in case of a data drive failure (e.g., data drive 150-1), the other two data drives (e.g., 150-2, 150-3) can continue to supply the necessary data and reconstruct the data using the parity information 155-2, 155-3. It further allows for a hot-swap of the failed data drive 150-1.

The typical function of the RAID 5 controller 140 is to receive the write requests and direct them to the desired data drives, as well as generating the associated parity information 155. During read operations, the RAID 5 controller 140 reads the data from data drives 150-1 to 150-3, checks the received data against the parity information 155-1 to 155-3, and returns valid data to the array.

A RAID 6 array uses the distributed parity concept of a RAID 5 array and adds an additional level of complexity with respect to the calculation of the data parity values. A RAID 6 array executes two separate parity computations, instead of a single parity computation as in a RAID 5 array. The results of the two independent parity computations are stored on different data drives. Therefore, even if two data drives fail (i.e., one data drive affecting only data and the other data drive affecting only parity computations), the surviving parity computations can be used to rebuild the missing data.

Using these basic RAID levels as building blocks, several storage system developers have created hybrid RAID levels that combine features from the original RAID levels. The most common hybrid RAID levels are RAID 10, RAID 30 and RAID 50.

A RAID 10 array uses mirrored data drives (e.g., a RAID 1 array) with data striping (e.g., a RAID 0 array). In one RAID 10 implementation (i.e., a RAID 0+1 array), data is striped across mirrored sets of data drives. This is referred to as a “stripe of mirrors.” In an alternative RAID 10 implementation (i.e., a RAID 1+0 array), data is striped across several data drives, and the entire RAID array is mirrored by at least one other array or data drives. This is referred to as “mirror of stripes.”

Referring to FIG. 1C, a RAID 30 array is illustrated. In this case, a hybrid approach is used where data is striped across two or more RAID 3 arrays. In the RAID 30 array 160, a RAID 30 controller 170 controls access to two or more parallel paths of data drives 180-1 to 180-9 and parity disks 190-1 to 190-3. This provides for a higher performance due to the capability of higher levels of parallel accesses to write and read data from the data drives, as well as better handling of data drive failures if and when they occur. Similar hybrid architecture may be used to create a RAID 50 array where the stripes use RAID 5 data arrays.

It is apparent that the RAID concept is limited to a local implementation where the disk arrays are in close proximity to a RAID controller. It would be advantageous to implement a RAID array that could be deployed over standard computer networks by taking advantage of newly developed network storage protocols, such as Internet small computer storage interface (iSCSI), small computer storage interface (SCSI) remote direct memory access (RDMA) protocol (SRP) over local area networks (LAN) in a variety of implementations such as Infiniband and Ethernet.

### SUMMARY OF THE PRESENT INVENTION

The present invention has been made in view of the above circumstances and to overcome the above problems and limitations of the prior art.

Additional aspects and advantages of the present invention will be set forth in part in the description that follows and in part will be obvious from the description, or may be learned by practice of the present invention. The aspects and advantages of the present invention may be realized and attained by means of the instrumentalities and combinations particularly pointed out in the appended claims

A first aspect of the present invention provides a network RAID controller that comprises a microcontroller having a plurality of operation instructions, a multi-port memory connected to the microcontroller, and a FIFO device connected to the multi-port memory. The FIFO device is capable of interfacing with a network. The RAID controller further comprises a map memory connected to the microcontroller, and the map memory stores address maps. Depending upon the RAID implementation, the RAID controller may further comprise a parity generator.

A second aspect of the present invention provides a network RAID controller that comprises an embedded computer that has a plurality of operation instructions that command the embedded computer. A multi-port memory is connected to the embedded computer, as well as a FIFO device that is connected to the multi-port memory. The FIFO device is capable of interfacing with a network. The RAID controller further comprises a map memory connected to the embedded computer, and the map memory stores address maps. Again, depending upon the RAID implementation, the RAID controller may further comprise a parity generator.

A third aspect of the present invention provides a network RAID controller that comprises control means, and means for storing a plurality of operation instructions, which is connected to said control means. The RAID controller further comprises a multi-port memory means connected to the control means, as well as means for interfacing that is connected to the multi-port memory means. The interfacing means is capable of interfacing with an external network. The network RAID controller further comprises means for storing address maps, and this means is connected to the control means. Depending upon the RAID implementation, the RAID controller may further comprise a means for generating parity.

A fourth aspect of the present invention provides a network RAID controller that comprises computing means with a plurality of operation instructions to command the computing means, and a multi-port memory means connected to the computing means. The RAID controller further comprises means for interfacing connected to the multi-port memory means, and the interfacing means is capable of interfacing with an external network. The RAID controller also includes a means for storing address maps, which is connected to said computing means. If required by the particular RAID implementation, the RAID controller may further comprise a means for generating parity.

A fifth aspect of the invention provides a computer network that comprises a primary network, a host computer connected to the primary network, and a secondary network. A network RAID controller connected to the primary network and to the secondary network. The computer network also comprises a plurality of group units, and each of the group units comprises a local bus, a plurality of data drives connected to the local bus, and a group unit RAID controller connected to the local bus. The group unit RAID controller is also connected to the secondary network.

A sixth aspect of the present invention provides a computer network that comprises a host computer connected to a network, and a network RAID controller connected to the network. There can be multiple network RAID controllers connected to the network. The RAID controller executes a mapping function that maps addresses supplied by the host computer to storage addresses. There is at least one data storage device connected to the network.

A seventh aspect of the present invention is a computer network that comprises a host computer connected to a first network, and at least one data storage device connected a second network. The computer network further comprises at least one network RAID controller connected to the first network and to the second network. The network RAID controller executes a mapping function that maps addresses supplied by the host computer to storage addresses at the data storage device on the second network. Multiple network RAID controllers can be used.

An eighth aspect of the present invention is a computer network that comprises a host computer connected to a first network and a second network. The computer network further comprises a network RAID controller connected to the first network and to the second network. The network RAID controller maps addresses supplied by the host computer to storage addresses. The computer network further comprises a plurality of group units. Each group unit comprises a local network, a plurality of data drives connected to the local network, and a group unit RAID controller for mapping addresses supplied by the host computer to storage addresses. The group unit RAID controller connected to the second network.

A ninth aspect of the present invention provides a method for accessing a networked RAID system comprising a network RAID controller and a plurality of data drives. The method comprises providing host addresses for storage access requests, requesting a storage access by accessing the network RAID controller, and generating at least two network storage addresses. The method further comprises accessing the plurality of data drives using the generated network storage addresses.

The above aspects and advantages of the present invention will become apparent from the following detailed description and with reference to the accompanying drawing figures.

### BRIEF DESCRIPTION OF THE DRAWINGS

The accompanying drawings, which are incorporated in and constitute a part of this specification, illustrate the present invention and, together with the written description, serve to explain the aspects, advantages and principles of the present invention. In the drawings,

FIG. 1A is a schematic diagram illustrating a conventional RAID 1 storage array;

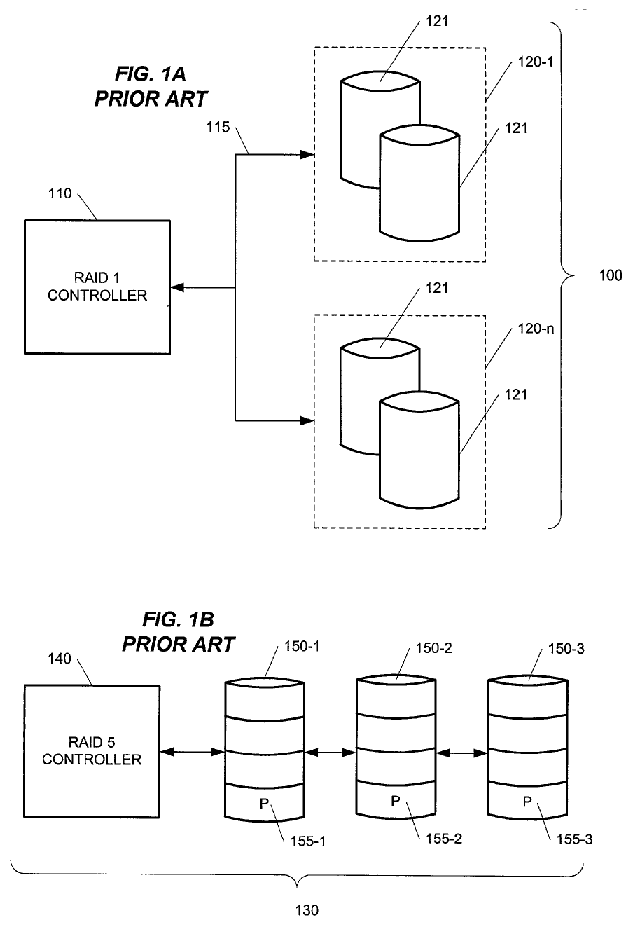

FIG. 1B is a schematic diagram illustrating a conventional RAID 5 storage array;

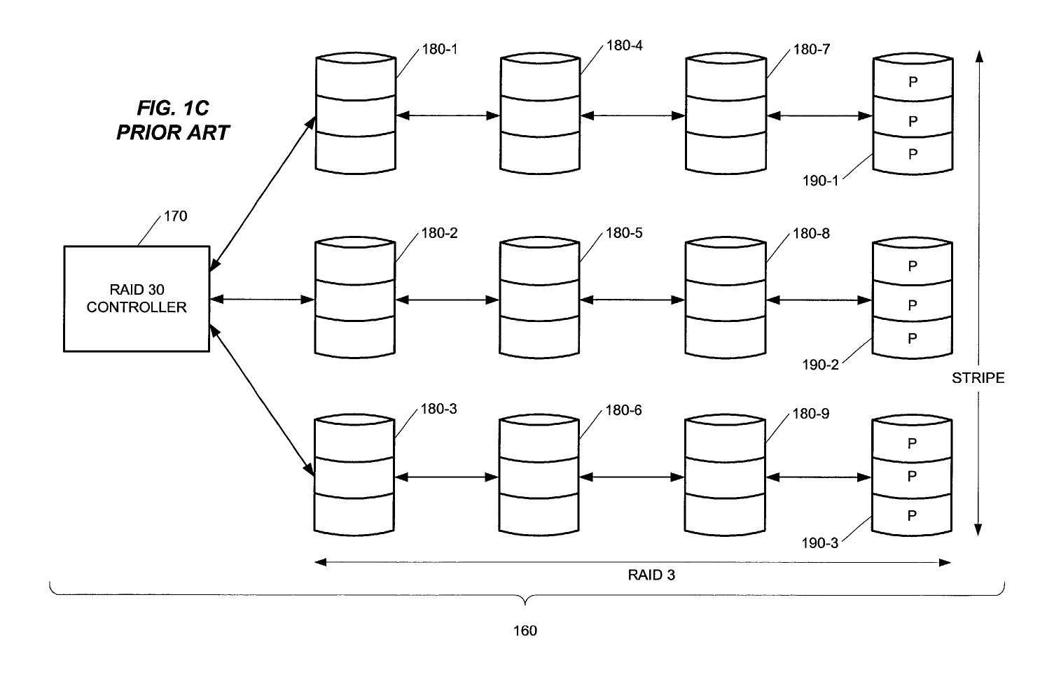

FIG. 1C is a schematic diagram illustrating a conventional RAID 30 storage array;

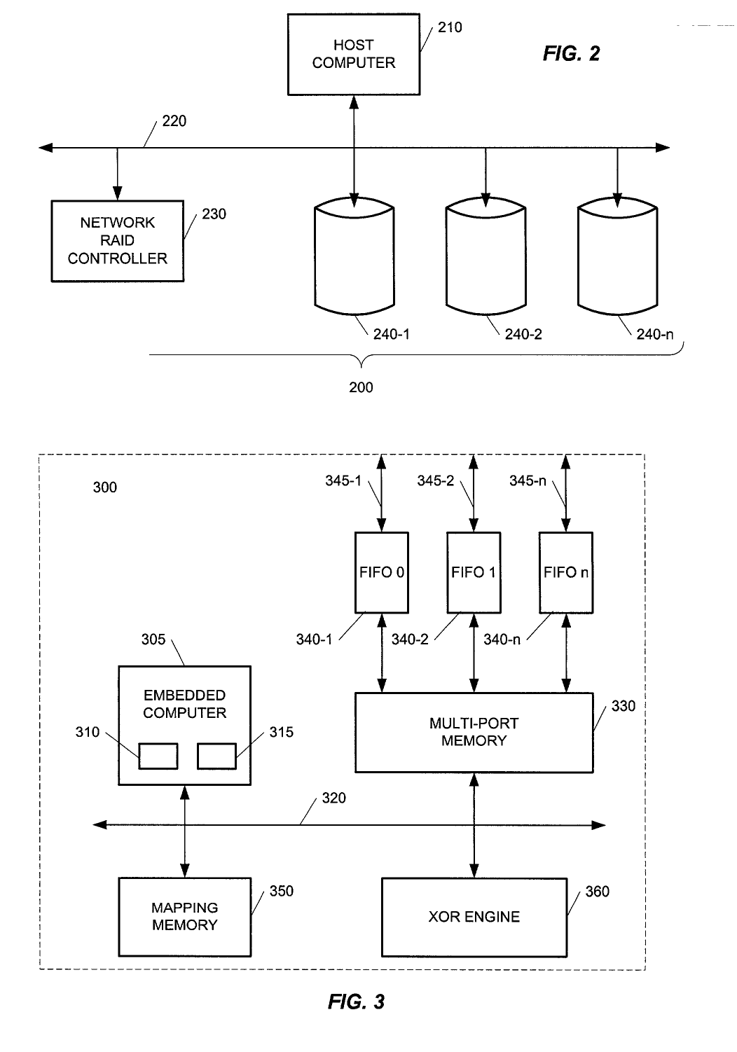

FIG. 2 is a schematic diagram illustrating an exemplary embodiment of a networked RAID storage array according to the present invention;

FIG. 3 is a block diagram illustrating an exemplary network RAID controller (NRC) according to the present invention;

FIG. 4 is an illustration of the mapping host supplied addresses to storage device addresses;

FIGS. 5A-5B are process flow diagrams illustrating a data write request using a network RAID controller (NRC) according to the present invention;

FIGS. 6A-6B are process flow diagrams illustrating a data read request using a network RAID controller (NRC) according to the present invention;

FIG. 7 is a block diagram of an exemplary embodiment of a networked RAID storage system according to the present invention;

FIG. 8 is a block diagram of an exemplary embodiment of a cascaded networked RAID according to the present invention; and

FIG. 9 is a block diagram of an exemplary embodiment of a cascaded networked RAID over a single network according to the present invention.

### DETAILED DESCRIPTION OF THE PRESENT INVENTION

Prior to describing the aspects of the present invention, some details concerning the prior art will be provided to facilitate the reader's understanding of the present invention and to set forth the meaning of various terms.

used herein, the term “computer system” encompasses the widest possible meaning and includes, but is not limited to, standalone processors, networked processors, mainframe processors, and processors in a client/server relationship. The term “computer system” is to be understood to include at least a memory and a processor. In general, the memory will store, at one time or another, at least portions of executable program code, and the processor will execute one or more of the instructions included in that executable program code.

As used herein, the term “embedded computer” includes, but is not limited to, an embedded central processor and memory bearing object code instructions. Examples of embedded computers include, but are not limited to, personal digital assistants, cellular phones and digital cameras. In general, any device or appliance that uses a central processor, no matter how primitive, to control its functions can be labeled has having an embedded computer. The embedded central processor will execute one or more of the object code instructions that are stored on the memory. The embedded computer can include cache memory, input/output devices and other peripherals.

As used herein, the terms “predetermined operations,” the term “computer system software” and the term “executable code” mean substantially the same thing for the purposes of this description. It is not necessary to the practice of this invention that the memory and the processor be physically located in the same place. That is to say, it is foreseen that the processor and the memory might be in different physical pieces of equipment or even in geographically distinct locations.

As used herein, the terms “media,” “medium” or “computer-readable media” include, but is not limited to, a diskette, a tape, a compact disc, an integrated circuit, a cartridge, a remote transmission via a communications circuit, or any other similar medium useable by computers. For example, to distribute computer system software, the supplier might provide a diskette or might transmit the instructions for performing predetermined operations in some form via satellite transmission, via a direct telephone link, or via the Internet.

Although computer system software might be “written on” a diskette, “stored in” an integrated circuit, or “carried over” a communications circuit, it will be appreciated that, for the purposes of this discussion, the computer usable medium will be referred to as “bearing” the instructions for performing predetermined operations. Thus, the term “bearing” is intended to encompass the above and all equivalent ways in which instructions for performing predetermined operations are associated with a computer usable medium.

Therefore, for the sake of simplicity, the term “program product” is hereafter used to refer to a computer-readable medium, as defined above, which bears instructions for performing predetermined operations in any form.

As used herein, the term “network switch” includes, but is not limited to, hubs, routers, ATM switches, multiplexers, communications hubs, bridge routers, repeater hubs, ATM routers, ISDN switches, workgroup switches, Ethernet switches, ATM/fast Ethernet switches and CDDI/FDDI concentrators, Fiber Channel switches and hubs, InfiniBand Switches and Routers.

A detailed description of the aspects of the present invention will now be given referring to the accompanying drawings.

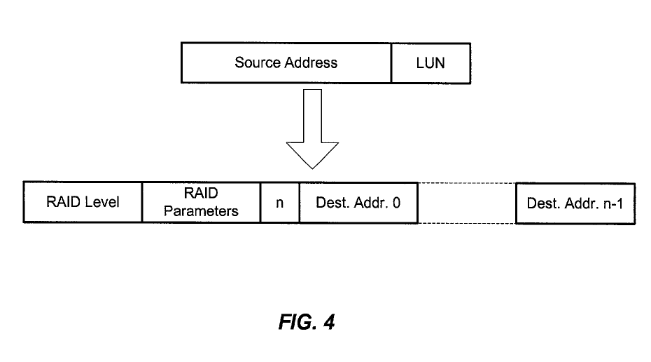

Referring to FIG. 2, an exemplary embodiment of the present invention is illustrated. The networked RAID system 200 comprises a host computer 210. The host computer 210 is capable of performing write operations to a data storage device, as well as read operations from the data storage device. The host computer 210 is connected to a computer network 220. A network RAID controller (NRC) 230 is connected to the network 220, as well as two or more data drives units 240-1 to 240-n, where n is the number of data drives in the networked RAID system 200. The NRC 230 is responsible for performing the network RAID functions as described below. Data drives 240-1 to 240-n are storage elements capable of storing and retrieving data according to instructions from the NRC 230. The computer network 220 is not limited to a local area network (LAN), and can be other implementations, wired or wireless, local or geographically distributed, such as a wide-area network (WAN). An artisan could easily implement a RAID system containing multiple network RAID controllers.

To perform a data write operation, the host computer 210 sends the data to be stored to the NRC 230. The NRC 230 has a known network address which supports the data write operation using network storage protocols, e.g., iSCSI or SRP. In order to perform the RAID function, the NRC 230 must map the data write request received from the host computer 210 into data write operations targeted at two or more of data drives 240-1 to 240n. The data write operations will be done in accordance with the specific mode of required RAID operation. For example, the NRC 230 could perform a RAID 1 function, wherein the mirroring capability of this RAID specification is executed. Hence, the data to be written will be mirrored in to two disks. Alternatively, the NRC 230 could perform a RAID 5 function, wherein the parity capability of this RAID specification is executed, as well as the other RAID functions defined for this level of RAID. In fact, the NRC 230 could perform one type of RAID function when data write operations are done to certain network addresses, while performing another type of RAID function when other network addresses are accessed. A more detailed explanation of the operation of the NRC 230 is provided below.

The host computer 210 can perform a data read operation from storage by requesting the desired data from the NRC 230. The Host computer 210 sends a data read request to the known network address of the NRC 230. The NRC 230 uses its internal mapping scheme to generate a data read request to read the data from the data drives 240-1 to 240-n. When the data arrives at the NRC 230 and is validated, the data is then sent to the requesting host computer 210.

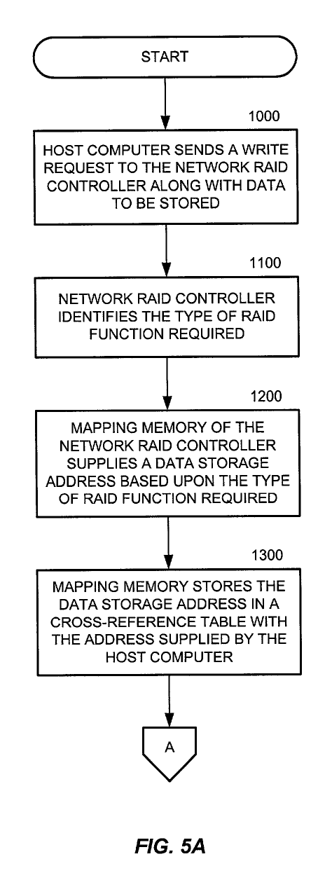

Referring to FIG. 3, an exemplary implementation of a NRC is shown. The NRC 300 can be implemented from discrete components or as an integrated circuit. The NRC 300 comprises an embedded computer 305. Preferably, the embedded computer 305 comprises a microcontroller 310 with software instructions 315 stored in a non-volatile memory. Preferably, the non-volatile memory can be rewritten with new software instructions as necessary. The non-volatile memory can be part of the microcontroller 310 or discrete components. The non-volatile memory may be updated in a variety of ways, such as a dedicated communication link, e.g. serial port like RS-232, electrically erasing and writing the data like in a flash or EEPROM, etc. The microcontroller 310 is connected to an internal bus 320. A multi-port memory 330 is connected to the internal bus 320. The multi-port memory is connected to one or more first-in, first-out (FIFO) devices 340-1 to 340-n. The FIFO devices 340-1 to 340-n provide the network interfaces 345-1 to 345-n that are connected to one or more system networks, such as network 220 illustrated in FIG. 2. Network interfaces 345-1 to 345-n may be standard or proprietary network interfaces. Preferably, standard communication protocol interfaces such as Ethernet, asynchronous transfer mode (ATM), iSCSI, InfiniBand, etc. would be used. In an embodiment of the present invention, all FIFO units may be connected to a single network interface. In another embodiment of the present invention, each FIFO may be connected to a separate network. In another embodiment of the present invention, each FIFO may implement a different type of network, i.e., Ethernet, ATM, etc. The network interface 345 is used for communicating with both the host computer 210 and the data drives 240. This allows for the implementation of a cascading of multiple NRC units through a standard network interface.

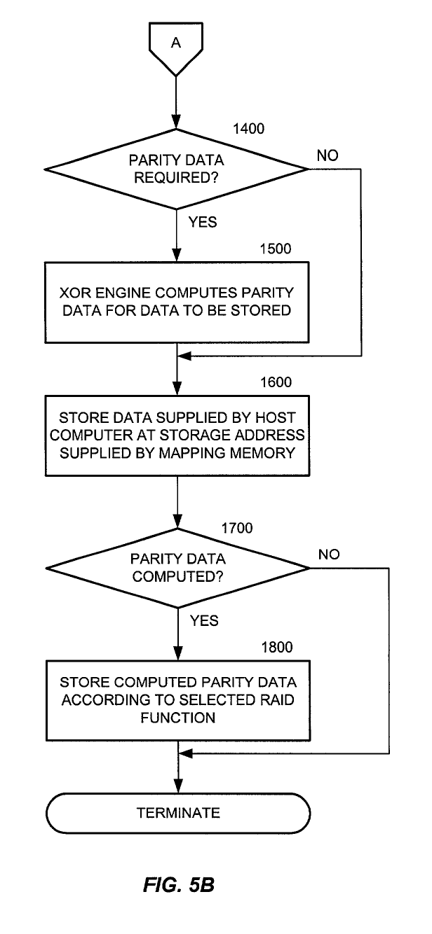

The NRC 300 further comprises a mapping memory 350 that is used for mapping host supplied addresses to storage device addresses and is connected to the internal bus 320. Referring to FIG. 4, the mapping is schematically shown. It should be noted that host computer supplied addresses might include source addresses, destination addresses and logical unit numbers (LUN), all of which are the logical number for the storage device. It should be further noted that for the purpose of cascaded operation the host-supplied address is actually provided by a NRC of the previous stage. The host information is mapped into a desired RAID level, RAID parameters, such as stripe size, number of destinations n, which is in fact that width of the RAID, or the number of disks used, and destination addresses corresponding to the number of disks. Hence, if there are two disks, then up to two destination addresses may be generated. The mapping table may be loaded into NRC 300 at initialization, as part of a system boot process. They may be updated during operation as system configuration changes or certain elements of the system are added or removed from the system. Such updates may take place through dedicated communication channels, writing to non-volatile memory, and the like.

The NRC 300 further comprises an exclusive OR (XOR) engine 360 is connected to the internal bus 320. The XOR engine 360 performs the parity functions associated with the operations of RAID implementations that use parity functions. The NRC 300 stores the values generated by the XOR engine on the data drives according to the type of RAID level being implemented.

The NRC 300 receives write requests from a host computer through the FIFO devices 340-1 to 340-n that is connected to the computer network through the network interface 345. The components of the request, i.e. source address, data and optionally the LUN, are stored in the multi-port memory 330. In the embedded computer 305, the microcontroller 310 executes the software instructions 315. The instructions executed are designed to follow the required RAID level for the data from the respective source.

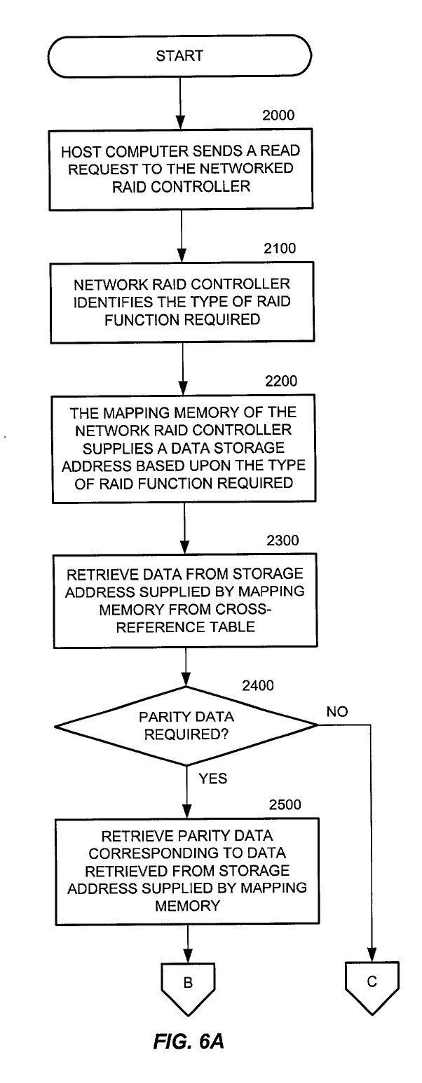

Referring to FIGS. 5A-5B, the exemplary software instructions 315 with respect to write requests will be described in more detail. At S1000, the host computer sends a write request to the NRC, along with the data, or at least pointers to data, to be stored on a data drive. The information is directed through a FIFO to the multi-port memory for the necessary processing. At S1100, the NRC identifies the type of RAID function required. In the present invention, the NRC could perform one type of RAID function when data write operations are done to or from certain network addresses, while performing another type of RAID function when other network addresses are accessed. At S1200, the mapping memory of the NRC supplies a storage address or addresses based upon the RAID function required. At S1400, a determination is made if parity data is to be generated. This determination is made based upon the RAID function identified in S1100. If no parity data is to be generated, then the process flow proceeds to S1600. At S1500, if parity data is to be generated, the XOR engine of the NRC generates parity information based on the data to be written to the data drive and the type of RAID function required. At S1600, the data is written to a FIFO destined to a data drive according to the storage address provided at S1200 and which will be sent to the network when all previous requests were handled by that FIFO. At S1700, a determination is made if parity information was calculated based upon the RAID function selected. If parity information was generated, then, as S1800, the parity information is written to a FIFO destined to a data drive according to the RAID function selected.

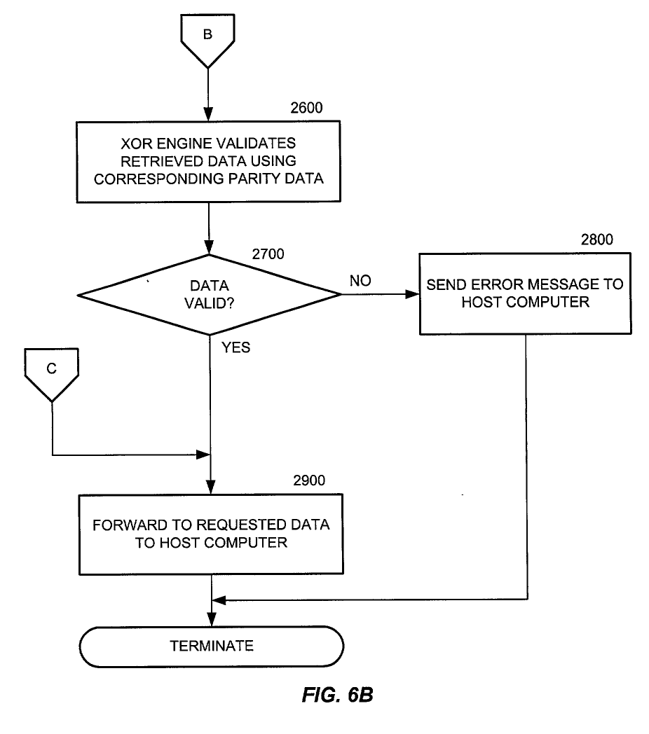

Referring to FIGS. 6A-6B, the software instructions 315 with respect to read requests will be described in more detail. The NRC 230 receives data read requests through the FIFO device 340 that is connected to the computer network through the FIFO interface 345. Information relative to the data read request, such as source address, destination address, or LUN is destined through the FIFO and stored in multi-port memory 330. In the embedded computer 305, the microcontroller 310 executes the software instructions 315. The instructions executed are designed to follow the required RAID level for the data from the respective source.

Referring to FIGS. 6A-6B, the software instructions 315 with respect to read requests will be described in more detail. At S2000, the host computer sends a read request to the NRC. The information is directed through a FIFO to the multi-port memory for the necessary processing. At S2100, an identification of the type of RAID system used for the storage of the data to be retrieved is made. At S2200, the mapping memory of the NRC supplies the microcontroller of the NRC with a storage address (or addresses) that is appropriate to the RAID operation required. At S2300, the microcontroller of the NRC reads the requested data from the data drives using the address or addresses supplied at S2200. At S2400, a determination is made whether any parity data is required to be read along with the requested data. If parity information is not required, the process flow proceeds to S2900. Otherwise, at S2500, the applicable parity information is read from the data drives. At S2600, the XOR engine of the NRC validates the requested data by using any calculated parity information that corresponds to the requested data.

At S2700, a determination is made whether the retrieved data is valid based on the corresponding parity information. If the data is invalid, then at S2800, an error message is sent to the host computer. Otherwise, at S2900, the microcontroller forwards the requested data to the host computer.

The present invention can perform cascaded RAID accesses by mapping a host address to addresses that access a NRC and repeating the steps described above. For example, for the purposes of a RAID 1 level implementation, the NRC can translate a data write request from the host computer at a first level. As a result, at least two write addresses will be generated in response to a single write request from host computer. The first write address mapping may be to a data drive, while the second write address may be the address of the NRC. In response to this data write request, the NRC may generate a data write request as a RAID 5 controller. As a result, additional write addresses will be generated, as well as parity information, in order to conform to a RAID 5 implementation.

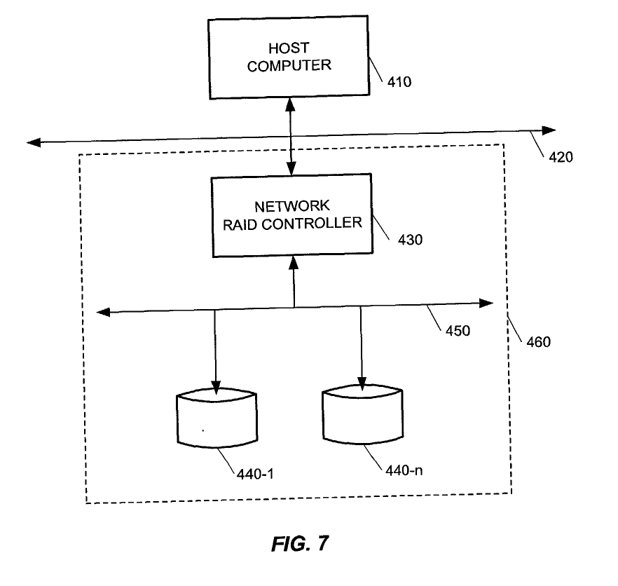

Referring to FIG. 7, an exemplary architecture for a networked RAID implementation is illustrated. In the exemplary system shown in FIG. 7, a host computer 410 and a NRC 430 are connected to a primary network 420. The NRC 430 is further connected to data drives 440-1 to 440-n through a local network 450, wherein n represents the number of data drives connected to the local network 450. The NRC 430 and data drives 440-1 to 440-n are referenced as a group unit 460. By using this architecture, a performance improvement is achieved as less data transfers occur over the primary network 420. For example, when the host computer 410 generates a data write request, the resultant data write operations to the data drives 440-1 to 440-n occur on the local network 450, rather than on the primary network 420. The reduced load on the primary network 420 results in an overall improvement to the performance of this system in comparison to system 200 depicted in FIG. 2. However, it should be noted that the NRC 430 may be accessed from either the primary network 420 or the local network 450, as may be deemed necessary and efficient for the desired implementation. In another embodiment of the present invention, the selection of which network to use (i.e., primary network 420 or local network 450) can result from a load comparison between the primary network 420 and the local network 420. The network selection is based on the usage of the least loaded network. A person skilled in the art could easily connect multiple group units 460 to the primary network 420.

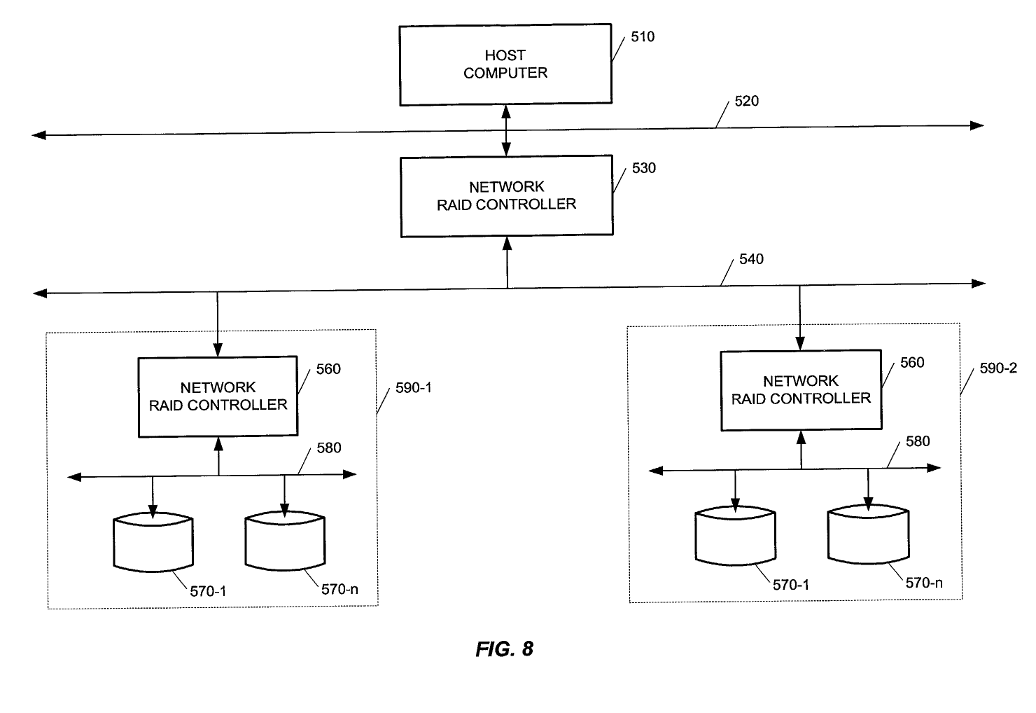

Referring to FIG. 8, an exemplary embodiment of a cascaded networked RAID system according to the present invention is illustrated. In the system, the host computer 510 and a NRC 530 are connected to a first network 520. The NRC 530 is connected to a first group unit 590-1 and a second group unit 590b through a secondary network 540. In each group unit, a NRC 560 is connected to the data drives 570-1 to 570-n through a local network 580. The NRC 560 of each group unit 590-1 to 590-2 is connected to the secondary network 540.

When a data write request from the host computer 510 reaches the NRC 530, the mapping of the host computer 510 supplied address can be done to the first or second group units 590-1 to 590-2. In an alternative embodiment, the NRC 530 will reference itself (see explanation above) and therefore the supplied address source can be either host computer 510 or the NRC 530. The supplied address can include, but is not limited to, source addresses, destination addresses and logical unit numbers (LUN), which are the logical number for the storage device.

Data write operations to a group unit 590 are handled in a similar way as described above. Overall performance is increased due to the reduction of network traffic in each network segment. In addition, it allows for a low cost implementation of multiple RAID functions within the system. A RAID 30 array can be easily implemented by configuring the NRC 530 to perform a RAID 0 function, hence taking care of the striping feature of a RAID solution. By configuring the NRC 560 of the group units 590 as RAID 30 controllers, a full RAID 30 implementation is achieved. A significant simplification of a RAID 30 array is achieved, as there is no dedicated RAID 30 controller and a flexible and easily adaptable system, using standard NRC building blocks is used. Similarly, a RAID 50 array would be implemented by configuring the NRC 560 of the group units 590 as RAID 5 controllers. Moreover, the same group unit 590 may be configured to provide RAID 30 and RAID 50 features depending on the specific information, such as source address, destination address, LUN or other parameters supplied. In order to support these advanced configurations, the NRC software instructions 315 and the NRC mapping memory 350 have to implement the configurations that a system is anticipated to be required to support. Such software can be loaded into the an NRC during manufacturing, for example in a read only memory (ROM) portion, loaded into non-volatile memory, e.g., flash or EEPROM, or otherwise loaded into NRC code memory through a communication link, e.g., RS-232, network link, etc. Such software may be further updated at a later time using similar implementations, though code stored in ROM is permanent and cannot be changed. It is customary to provide certain software hooks to allow for an external code memory extensions to support upgrade, bug fixing, and changes when ROM is used. Similarly the mapping memory can be loaded and updated using similar provisions. By allowing code memory to have an extension memory, or other memory accessible by a user, using basic building blocks such as RAID 0, RAID 1, RAID 3 and RAID 5 can allow for additional implementations of RAID systems. More specifically, a RAID 31 configuration could be implemented by configuring the NRC 530 as a RAID 1 controller and NRC 560 as a RAID 3, hence implementing the reliability capabilities beyond the basic striping.

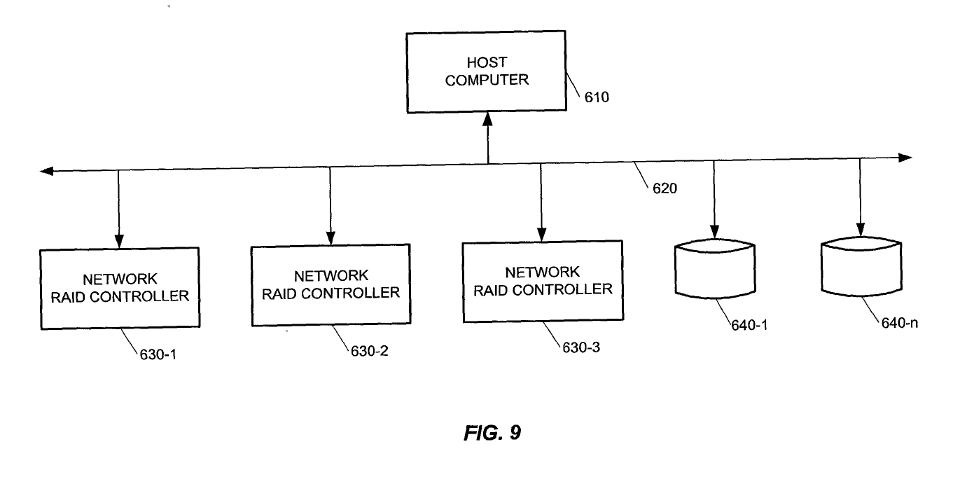

Referring to FIG. 9, the flexibility of the present invention can be further demonstrated where the use of the standard network interface becomes apparent. In the system, all the network elements are connected to a primary network 620. A plurality of NRCs is connected to the primary network 620, i.e., NRCs 630-1 to 630-3. There are no limitations on the number of NRCs that can be connected to the primary network 620. Data drives 640-1 to 640-n are also connected directly to the primary network 620, wherein n represents the number of data drives connected to the primary network 620. When the host computer 610 wishes to access the data drives 240-1 to 240-n, the host computer 610 sends an access request to one of the plurality of NRCs 630. The NRC that receives the data request from the host computer 610 responds according to its configuration (i.e., software instructions 315 and mapped memory 350). For example, the NRC could request the data from the data drives 640-1 to 640-n or could send the data request to another NRC, which then handles the transfer from the data drives 6401 to 640-n.

More specifically, a RAID 30 array could be implemented by configuring the NRC 630-1 as a RAID 0 controller and the second NRC 630-2 as RAID 3 controller. The present invention could be expanded using the capabilities and flexibility of the NRC to additional configurations and architectures to create a variety of RAID implementations. It should be further noted that a single NRC could also be used to implement a more complex RAID structure. For example, the software instructions 315 and the mapped memory 350 of the NRC 230 of FIG. 2 could configured such that:

1. On storage accesses from the host computer 210, it operates as a RAID

0 implementation with address mapping back to the same NRC 230; and

2. On storage accesses from NRC 230, it operates as a RAID 3 implementation with address mapping to the data storage.

It should be noted that in certain cases the performance of a RAID array according to the present invention might be inferior to previously proposed solutions. The simplicity and low cost, however, of the present invention may be of significant value for low-cost RAID implementations.

The foregoing description of the aspects of the present invention has been presented for purposes of illustration and description. It is not intended to be exhaustive or to limit the present invention to the precise form disclosed, and modifications and variations are possible in light of the above teachings or may be acquired from practice of the present invention. The principles of the present invention and its practical application were described in order to explain the to enable one skilled in the art to utilize the present invention in various embodiments and with various modifications as are suited to the particular use contemplated.

Thus, while only certain aspects of the present invention have been specifically described herein, it will be apparent that numerous modifications may be made thereto without departing from the spirit and scope of the present invention. Further, acronyms are used merely to enhance the readability of the specification and claims. It should be noted that these acronyms are not intended to lessen the generality of the terms used and they should not be construed to restrict the scope of the claims to the embodiments described therein.

What is claimed is:

1. A network RAID controller comprising:
a microcontroller having a plurality of operation instructions;
a multi-port memory connected to said microcontroller;
at least one FIFO device connected to said multi-port memory, said at least one FIFO device capable of interfacing with a network; and
a map memory connected to said microcontroller, said map memory storing address maps.

2. The network RAID controller as claimed in claim 1, further comprising a parity device connected to said microcontroller.

3. The network RAID controller as claimed in claim 1, wherein said plurality of operation instructions comprise object code instructions that are adapted to implement a plurality of RAID functions.

4. The network RAID controller as claimed in claim 3, wherein said object code instructions implement at least one of RAID 0, RAID 1, RAID 2, RAID 3, RAID 4, RAID 5, RAID 6, RAID 7, RAID 10, RAID 30 and RAID 50 functions.

5. The network RAID controller as claimed in claim 1, wherein said map memory further comprises a conversion table that converts addresses received from a host computer into addresses targeted to a data storage device.

6. The network RAID controller as claimed in claim 1, wherein said map memory further comprises a conversion table that converts addresses received from a host computer into network addresses.

7. The network RAID controller as claimed in claim 2, wherein said parity device generates at least odd parity information.

8. The network RAID controller as claimed in claim 2, wherein said parity device generates at least even parity information.

9. The network RAID controller as claimed in claim 4, further comprising a parity device connected to said microcontroller, said parity device generates parity information based upon the type of RAID function implemented.

10. The network RAID controller as claimed in claim 2, wherein said parity device and said microcontroller perform an error correction function.

11. The network RAID controller as claimed in claim 1, wherein said at least one FIFO device is a plurality of FIFO devices.

12. The network RAID controller as claimed in claim 2, wherein said parity device is an exclusive-OR engine.

13. The network RAID controller as claimed in claim 1, said microcontroller further comprising an instruction memory storing said plurality of operation instructions;

14. A computer network comprising:
a network;
a host computer connected to said network;
a plurality of data drives connected to said network; and
a network RAID controller as claimed in claim 1, said network RAID controller connected to said network.

15. A computer network comprising:
a network;
a host computer connected to said network;
a plurality of data drives connected to said network; and
a plurality of network RAID controllers as claimed in claim 1, wherein each of said plurality of network RAID controllers are connected to said network.

16. A computer network comprising:
a primary network;
a host computer connected to said primary network;
a secondary network;
a network RAID controller as claimed in claim 1, wherein said network RAID controller is connected to said primary network and to said secondary network; and
a plurality of data drives connected to said secondary network.

17. A network RAID controller comprising:
an embedded computer having a plurality of operation instructions;
a multi-port memory connected to said embedded computer;
at least one FIFO device connected to said multi-port memory, said at least one FIFO device capable of interfacing with a network;
a map memory connected to said embedded computer, said map memory storing address maps.

18. The network RAID controller as claimed in claim 17, further comprising a parity device connected to said embedded computer.

19. The network RAID controller as claimed in claim 17, wherein said plurality of operation instructions comprise object code instructions that are adapted to implement a plurality of RAID functions.

20. The network RAID controller as claimed in claim 19, wherein said object code instructions implement RAID 0, RAID 1, RAID 2, RAID 3, RAID 4, RAID 5, RAID 6, RAID 7, RAID 10, RAID 30 and RAID 50 functions.

21. The network RAID controller as claimed in claim 17, wherein said map memory further comprises a conversion table that converts addresses received from a host computer into addresses targeted to a data storage device.

22. The network RAID controller as claimed in claim 17, wherein said map memory further comprises a conversion table that converts addresses received from a host computer into network addresses.

23. The network RAID controller as claimed in claim 18, wherein said parity device generates at least odd parity information.

24. The network RAID controller as claimed in claim 18, wherein said parity device generates at least even parity information.

25. The network RAID controller as claimed in claim 20, further comprising a parity device connected to said embedded computer, said parity device generates parity information based upon the type of RAID function implemented.

26. The network RAID controller as claimed in claim 17, wherein said parity device and said embedded computer perform an error correction function.

27. The network RAID controller as claimed in claim 17, wherein said at least one FIFO device is a plurality of FIFO devices.

28. The network RAID controller as claimed in claim 18, wherein said parity device is an exclusive-OR engine.

29. The network RAID controller as claimed in claim 17, said embedded computer further comprising an instruction memory storing said plurality of operation instructions.

30. A computer network comprising:
a network;
a host computer connected to said network;
a plurality of data drives connected to said network; and
a network RAID controller as claimed in claim 17, said network RAID controller connected to said network.

31. A computer network comprising:
a network;
a host computer connected to said network;
a plurality of data drives connected to said network; and
a plurality of network RAID controllers as claimed in claim 17, wherein each of said plurality of network RAID controllers are connected to said network.

32. A computer network comprising:
a primary network;
a host computer connected to said primary network;
a secondary network;
a network RAID controller as claimed in claim 17, wherein said network RAID controller is connected to said primary network and to said secondary network; and
a plurality of data drives connected to said secondary network.

33. A network RAID controller comprising:
control means;
means for storing a plurality of operation instructions, said means connected to said control means;
a multi-port memory means connected to said control means;
means for interfacing connected to said multi-port memory means, said means for interfacing capable of interfacing with a network; and
means for storing address maps, said means connected to said control means.

34. The network RAID controller as claimed in claim 33, further comprising means for parity generation, said parity generation means connected to said control means.

35. The network RAID controller as claimed in claim 33, wherein said plurality of operation instructions comprise object code instructions that are adapted to implement a plurality of RAID functions.

36. The network RAID controller as claimed in claim 35, wherein said object code instructions implement RAID 0, RAID 1, RAID 2, RAID 3, RAID 4, RAID 5, RAID 6, RAID 7, RAID 10, RAID 30 and RAID 50 functions.

37. The network RAID controller as claimed in claim 33, wherein said means for storing address maps stores a conversion table that converts addresses received from a host computer into addresses targeted to a data storage device.

38. The network RAID controller as claimed in claim 33, wherein said means for storing address maps stores a conversion table that converts addresses received from a host computer into network addresses.

39. The network RAID controller as claimed in claim 34, wherein said means for parity generation generates odd parity information.

40. The network RAID controller as claimed in claim 34, wherein said means for parity generation generates even parity information.

41. The network RAID controller as claimed in claim 36, further comprising means for parity generation, said parity generation means generates parity information based upon the type of RAID function implemented.

42. The network RAID controller as claimed in claim 34, wherein said means for parity generation and said control means perform an error correction function.

43. The network RAID controller as claimed in claim 33, wherein said means for interfacing is a plurality of FIFO devices.

44. The network RAID controller as claimed in claim 34, wherein said means for parity generation is an exclusive-OR engine.

45. The network RAID controller as claimed in claim 33, said control means further comprises an instruction memory storing said plurality of operation instructions;

46. A network RAID controller comprising:
computing means having a plurality of operation instructions;
a multi-port memory means connected to said computing means;
means for interfacing connected to said multi-port memory means, said means for interfacing capable of interfacing with a network; and
means for storing address maps, said means connected to said computing means.

47. The network RAID controller as claimed in claim 46, further comprising means for parity generation, said parity generation means connected to said computing means.

48. The network RAID controller as claimed in claim 46, wherein said plurality of operation instructions comprise object code instructions that are adapted to implement a plurality of RAID functions.

49. The network RAID controller as claimed in claim 48, wherein said object code instructions implement RAID 0, RAID 1, RAID 2, RAID 3, RAID 4, RAID 5, RAID 6, RAID 7, RAID 10, RAID 30 and RAID 50 functions.

50. The network RAID controller as claimed in claim 46, wherein said means for storing address maps stores a conversion table that converts addresses received from a host computer into addresses targeted to a data storage device.

51. The network RAID controller as claimed in claim 46, wherein said means for storing address maps stores a conversion table that converts addresses received from a host computer into network addresses.

52. The network RAID controller as claimed in claim 47, wherein said means for parity generation generates odd parity information.

53. The network RAID controller as claimed in claim 47, wherein said means for parity generation generates even parity information.

54. The network RAID controller as claimed in claim 49, further comprising means for parity generation, said parity generation means connected to said computing means and said parity generation means generates parity information based upon the type of RAID function implemented.

55. The network RAID controller as claimed in claim 47, wherein said means for parity generation and said control means perform an error correction function.

56. The network RAID controller as claimed in claim 46, wherein said means for interfacing is a plurality of FIFO devices.

57. The network RAID controller as claimed in claim 47, wherein said means for parity generation is an exclusive-OR engine.

58. The network RAID controller as claimed in claim 46, said control means further comprises an instruction memory storing said plurality of operation instructions.

59. A computer network comprising:
a primary network;
a host computer connected to said primary network;
a secondary network;
a network RAID controller connected to said primary network and to said secondary network;
a plurality of group units, each of said group units comprising:
a local bus;
a plurality of data drives connected to said local bus;
a group unit RAID controller connected to said local bus, said group unit RAID controller also connected to said secondary network.

60. The computer network as claimed in claim 59, wherein each of said group unit RAID controllers comprise:
a microcontroller having a plurality of operation instructions;
a multi-port memory connected to said microcontroller;
a plurality of FIFO devices connected to said multi-port memory, wherein one of said plurality of FIFO devices is connected to said secondary network and one of said plurality of FIFO devices is connected to said local bus; and
a map memory connected to said microcontroller, said map memory storing address maps.

61. The group unit RAID controller as claimed in claim 60, further comprising a parity device connected to said microcontroller.

62. The group unit RAID controller as claimed in claim 60, wherein said plurality of operation instructions comprise object code instructions that are adapted to implement a plurality of RAID functions.

63. The group unit RAID controller as claimed in claim 62, wherein said object code instructions implement RAID 0, RAID 1, RAID 2, RAID 3, RAID 4, RAID 5, RAID 6, RAID 7, RAID 10, RAID 30 and RAID 50 functions.

64. The group unit RAID controller as claimed in claim 60, wherein said map memory further comprises an conversion table that converts addresses received from said host computer into addresses targeted to said plurality of data drives.

65. The group unit RAID controller as claimed in claim 63, further comprising a parity device connected to said microcontroller, wherein said parity device generates parity information based upon the type of RAID function implemented.

66. The group unit RAID controller as claimed in claim 61, wherein said parity device and said microcontroller perform an error correction function.

67. The group unit RAID controller as claimed in claim 61, wherein said parity device is an exclusive-OR engine.

68. The group unit RAID controller as claimed in claim 60, said microcontroller further comprising an instruction memory storing said plurality of operation instructions;

69. A computer network comprising:
a host computer connected to a network;
at least one network RAID controller connected to said network, said network RAID controller executes a mapping function that maps addresses supplied by said host computer to storage addresses; and
at least one data storage device connected to said network.

70. The computer network as claimed in claim 69, wherein said at least one network RAID controller executes a data mirroring function.

71. The computer network as claimed in claim 69, wherein said at least one network RAID controller computes parity information.

72. The computer network as claimed in claim 69, wherein said at least one network RAID controller executes an error correction function.

73. The computer network as claimed in claim 72, wherein said error correction function is performed based on parity information generated by said at least one network RAID controller.

74. The computer network as claimed in claim 69, wherein said mapping of storage addresses comprises:
identifying the RAID level required;
generating at least two storage addresses for the address supplied by the host computer; and
maintaining a cross-reference of said addresses supplied by said host computer to said generated storage addresses.

75. The computer network as claimed in claim 74, wherein generating at least two storage addresses for the address further comprises generating parity information corresponding to the data received from said host computer and in accordance with said required RAID level prior to writing the received data to said generated storage addresses.

76. The computer network as claimed in claim 75, wherein the received data and the generated parity information corresponding to the received data are written to said generated storage addresses.

77. The computer network as claimed in claim 74, wherein if data is requested from said at least one data storage device, said network RAID controller performs a read operation comprising:
retrieving the requested data using the storage addresses from the storage address cross-reference;
retrieving parity information from said storage addresses in accordance with said required RAID level;
checking the requested data read from said storage addresses against the retrieved parity information in accordance with said required RAID level;
if error is found, using error correcting techniques and the retrieved parity information to generate a corrected version of the requested data; and
forwarding the retrieved data to said host computer.

78. The computer network as claimed in claim 74, wherein at least one generated address is an address of said controller.

79. The computer network as claimed in claim 74, wherein generation of said storage addresses is a result of a pre-loaded conversion table to said network RAID controller.

80. A computer network comprising:
a host computer connected to a first network;
at least one data storage device connected a second network;
at least one network RAID controller connected to said first network and to said second network, said network RAID controller executes a mapping function that maps addresses supplied by said host computer to storage addresses.

81. The computer network as claimed in claim 80, wherein said at least one network RAID controller executes a data mirroring function.

82. The computer network as claimed in claim 80, wherein said at least one network RAID controller computes parity information.

83. The computer network as claimed in claim 80, wherein said at least one network RAID controller executes an error correction function.

84. The computer network as claimed in claim 83, wherein said error correction function is performed based on parity information generated by said at least one network RAID controller.

85. The computer network as claimed in claim 80, wherein said mapping of storage addresses comprises:
identifying the RAID level required;
generating at least two storage addresses for the address supplied by the host computer; and
maintaining a cross-reference of said addresses supplied by said host computer to said generated storage addresses.

86. The computer network as claimed in claim 85, wherein generating at least two storage addresses for the address further comprises generating parity information corresponding to the data received from said host computer and in accordance with said required RAID level prior to writing the received data to said generated storage addresses.

87. The computer network as claimed in claim 86, wherein the received data and the generated parity information corresponding to the received data are written to said generated storage addresses.

88. The computer network as claimed in claim 85, wherein if data is requested from said at least one data storage device, said network RAID controller performs a read operation comprising:
retrieving the requested data using the storage addresses from the storage address cross-reference;
retrieving parity information from said storage addresses in accordance with said required RAID level;
checking the requested data read from said storage addresses against the retrieved parity information in accordance with said required RAID level;
if error is found, using error correcting techniques and the retrieved parity information to generate a corrected version of the requested data; and
forwarding the retrieved data to said host computer.

89. The computer network as claimed in claim 85, wherein at least one generated address is an address of said network RAID controller.

90. The computer network as claimed in claim 85, wherein generation of said storage addresses is a result of a pre-loaded conversion table to said network RAID controller.

91. The computer network as claimed in claim 80, wherein said address from said host computer is sent over said first network.

92. The computer network as claimed in claim 80, wherein said storage addresses are sent over said second network.

93. A computer network comprising:
a host computer connected to a first network;
a second network;
a network RAID controller connected to said first network and to said second network, said network RAID controller for mapping addresses supplied by said host computer to storage addresses; and
a plurality of group units, each group unit comprising:
a local network;
a plurality of data drives connected to said local network; and
a group unit RAID controller for mapping addresses supplied by said host computer to storage addresses, said group unit RAID controller connected to said second network.

94. The computer network as claimed in claim 93, wherein said at least one network RAID controller executes a data mirroring function.

95. The computer network as claimed in claim 93, wherein said at least one network RAID controller computes parity information.

96. The computer network as claimed in claim 93, wherein said at least one network RAID controller executes an error correction function.

97. The computer network as claimed in claim 96, wherein said error correction function is performed based on parity information generated by said at least one network RAID controller.

98. The computer network as claimed in claim 93, wherein said mapping of storage addresses comprises:
identifying the RAID level required;
generating at least two storage addresses for the address supplied by the host computer; and
maintaining a cross-reference of said storage addresses supplied by said host computer to said generated storage addresses.

99. The computer network as claimed in claim 98, wherein said on of said storage addresses is an address of one of said group unit data drives.

100. The computer network as claimed in claim 98, wherein said network address is an address of one of said group unit RAID controllers.

101. The computer network as claimed in claim 98, wherein generating at least two storage addresses for the address supplied by the host computer further comprises generating parity information corresponding to the data received from said host computer and in accordance with said required RAID level prior to writing the received data to said generated storage addresses.

102. The computer network as claimed in claim 101, wherein the received data and the generated parity information corresponding to the received data are written to said generated storage addresses.

103. The computer network as claimed in claim 98, wherein if data is requested from said at least one data storage device, said network RAID controller performs a read operation comprising:
retrieving the requested data using the storage addresses from the storage address cross-reference;
retrieving parity information from said storage addresses in accordance with said required RAID level;
checking the requested data read from said storage addresses against the retrieved parity information in accordance with said required RAID level;
if error is found, using error correcting techniques and the retrieved parity information to generate a corrected version of the requested data; and
forwarding the retrieved data to said host computer.

104. The computer network as claimed in claim 98, wherein at least one of said generated storage addresses is an address of said first controller.

105. The computer network as claimed in claim 104, wherein at least one of said generated storage addresses is sent over said first network.

106. The computer network as claimed in claim 104, wherein at least one of said generated storage addresses is sent over said second network.

107. The computer network as claimed in claim 98, wherein at least one of said generated storage addresses is an address of one of said group unit network controllers.

108. The computer network as claimed in claim 98, wherein generation of said storage addresses is a result of a pre-loaded conversion table to said network RAID controller.

109. A method for accessing a networked RAID system comprising a network RAID controller and a plurality of data drives, comprising:
providing host addresses for storage access requests;
requesting a storage access by accessing the network RAID controller;
generating at least two network storage addresses; and
accessing said plurality of data drives using said network storage addresses.

110. The method as claimed in claim 109, said method further comprises loading an address conversion table for converting host addresses to said network storage addresses.

111. The method of claim 109, wherein said generated network addresses are generated based on RAID level required.

112. The method of claim 109, wherein at least one of said generated network addresses is the address of said network RAID controller.

113. The method of claim 109, wherein at least one of said generated network addresses is the address of a second network RAID controller.

114. The method of claim 109, wherein if said host computer issues a write request, the method further comprises:
checking if said RAID level requires parity support; and
generating parity information if said parity support is required.

115. The method of claim 109, the method further comprises writing received data and any generated parity information.

116. The method of claim 109, wherein if said host computer issues a write request, the method further comprises:
checking if said RAID level requires parity support;
if said parity support is required, the method further comprises:
reading parity information corresponding to said data; and
checking if retrieved data is correct, and if not, generating correct the retrieved data using error correcting techniques corresponding with said parity information;
forwarding the retrieved data to said host computer.
